(19) United States
(12) Patent Application Publication
(10) Pub. No.: US 2025/0210309 A1
(43) Pub. Date: Jun. 26, 2025

(54) SYSTEMS AND METHODS FOR CONTROLLING A POWER LIMITER

(71) Applicant: LAM RESEARCH CORPORATION, Fremont, CA (US)

(72) Inventors: Ranadeep BHOWMICK, San Jose, CA (US); John P. Holland, San Jose, CA (US)

(21) Appl. No.: 18/848,479

(22) PCT Filed: Mar. 16, 2023
(86) PCT No.: PCT/US23/15420

§ 371 Date: Sep. 18, 2024

Related U.S. Application Data
(60) Provisional application No. 63/325,404, filed on Mar. 30, 2022.

(51) Int. Cl. H01J 37/32

(52) U.S. Cl. CPC H01J 37/32183

(57) ABSTRACT

A method for controlling a limit on power supplied by a high frequency (HF) radio frequency (RF) generator is described. The method includes determining whether average power reflected towards the HF RF generator is less than a maximum limit, and determining whether power reflected towards the HF RF generator for a number of bins during a cycle is less than a predetermined threshold upon determining that the average power is less than the maximum limit. The method further includes determining whether a number of mistuned bins is greater than a predetermined number in response to determining that the power reflected towards the HF RF generator for the number of bins during the cycle is not less than the predetermined threshold. The method includes engaging a power limiter filter upon determining that the number of mistuned bins is not greater than the predetermined number.

### FIELD

The embodiments described in the present disclosure relate to systems and methods for controlling a power limiter.

### BACKGROUND

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A radio frequency (RF) generator generates an RF signal and supplies the RF signal. The RF generator is connected to an impedance matching circuit. The impedance matching circuit receives the RF signal and matches an impedance of a load to that of a source to output another RF signal. The other RF signal is supplied to a plasma chamber. A semiconductor wafer is placed in the plasma chamber for processing.

During processing of the semiconductor wafer, power of the RF signal generated by the RF generator is supplied to the semiconductor wafer. It is difficult to control the supply of power to process the semiconductor wafer in a desirable manner.

It is in this context that embodiments described in the present disclosure arise.

### SUMMARY

Embodiments of the disclosure provide systems and methods for controlling a power limiter. It should be appreciated that the present embodiments can be implemented in numerous ways, e.g., a process, an apparatus, a system, a piece of hardware, or a method on a computer-readable medium. Several embodiments are described below.

In one embodiment, a method for controlling a limit on power supplied by a high frequency (HF) radio frequency (RF) generator is described. The method includes determining whether average power reflected towards the HF RF generator is less than a maximum limit, and determining whether power reflected towards the HF RF generator for a number of bins during a cycle is less than a predetermined threshold upon determining that the average power is less than the maximum limit. The method further includes determining whether a number of mistuned bins is greater than a predetermined number in response to determining that the power reflected towards the HF RF generator for the number of bins during the cycle is not less than the predetermined threshold. The method includes engaging a power limiter filter upon determining that the number of mistuned bins is not greater than the predetermined number.

In an embodiment, a controller is described. The controller includes a processor that determines whether average power reflected towards the HF RF generator is less than a maximum limit, and determines whether power reflected towards the HF RF generator for a number of bins during a cycle is less than a predetermined threshold upon determining that the average power is less than the maximum limit. The processor determines whether a number of mistuned bins is greater than a predetermined number in response to determining that the power reflected towards the HF RF generator for the number of bins during the cycle is not less than the predetermined threshold. The processor engages a power limiter filter upon determining that the number of mistuned bins is not greater than the predetermined number. The controller includes a memory device coupled to the processor.

In one embodiment, a plasma system is described. The plasma system includes a low frequency (LF) RF generator. The LF RF generator generates an LF RF signal. The plasma system further includes an HF RF power supply, which generates an HF RF signal. The plasma system includes a match coupled to the LF and HF RF generators to receive the LF and HF RF signals to output a modified signal. The plasma system includes a plasma chamber coupled to the match to receive the modified signal. The plasma system also includes a controller coupled to the HF RF power supply. The controller determines whether average power reflected towards the HF RF generator is less than a maximum limit and determines whether power reflected towards the HF RF generator for a number of bins during a cycle is less than a predetermined threshold upon determining that the average power is less than the maximum limit. The controller determines whether a number of mistuned bins is greater than a predetermined number in response to determining that the power reflected towards the HF RF generator for the number of bins during the cycle is not less than the predetermined threshold. The controller engages a power limiter filter upon determining that the number of mistuned bins is not greater than the predetermined number.

Some advantages of the herein described systems and methods for controlling the power limiter including filtering out, such as removing, a limit on power that is supplied by an HF RF generator. For each bin, power to be supplied by the HF RF generator is determined. Also, for each bin, if there is an increase in the power, the power limiter limits the increase to protect components of the HF RF generator. However, sometimes, the limit is not necessary. For example, sometimes, during the bin, power reflected towards the HF RF generator is low and therefore, chances of damage to the components are low. As such, the limit is ignored and the power is increased to process a substrate with a higher processing rate.

Some other aspects will become apparent from the following detailed description, taken in conjunction with the accompanying drawings.

### BRIEF DESCRIPTION OF THE DRAWINGS

The embodiments are understood by reference to the following description taken in conjunction with the accompanying drawings.

FIG. 1 is a diagram of an embodiment of a plasma system to illustrate use of a low frequency (LF) radio frequency (RF) generator and a high frequency (HF) RF generator.

FIG. 2A is an embodiment of a graph to illustrate a clock signal.

FIG. 2B is a graph that plots an embodiment of a voltage signal to illustrate binning.

FIG. 2C is a diagram of an embodiment of a graph to illustrate generation of HF offset values at which the HF RF generator is to be operated during processing of a substrate.

FIG. 3A is a diagram of an embodiment of a system to illustrate a power limiter filter.

FIG. 3B is a flowchart to illustrate an embodiment of a method for determining whether to limit power that is supplied by the HF RF generator.

### DETAILED DESCRIPTION

The following embodiments describe systems and methods for controlling a power limiter. It will be apparent that the present embodiments may be practiced without some or all of these specific details. In other instances, well known process operations have not been described in detail in order not to unnecessarily obscure the present embodiments.

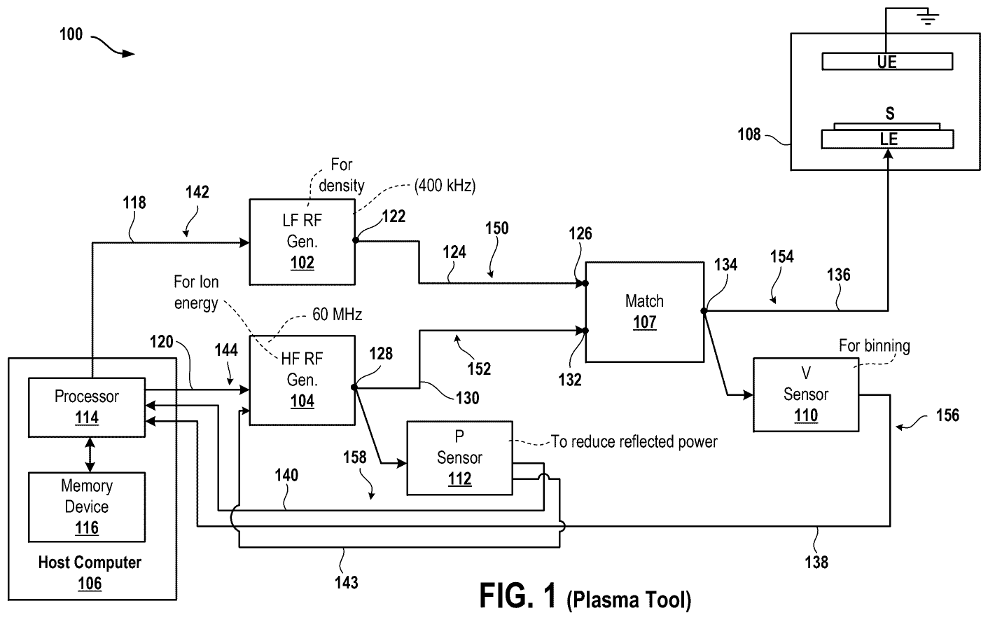

FIG. 1 is a diagram of an embodiment of a plasma system 100 to illustrate use of a low frequency (LF) RF generator 102 and an HF RF generator 104. The system 100 includes the LF RF generator 102, the HF RF generator 104, a host computer 106, a match 107, and a plasma chamber 108. The plasma system 100 further includes a voltage (V) sensor 110 and a power (P) sensor 112.

As an example, the LF RF generator 102 has a frequency of operation of 400 kilohertz (kHz), or 2 megahertz (MHz). Also, as an example, the HF RF generator 104 has a frequency of operation of 27 MHz or 60 MHz. Examples of the host computer 106 include a desktop, a laptop, a tablet, a controller, and a smart phone. An example of the match 107 is an impedance matching circuit or an impedance match or a match circuit or an impedance matching network. To illustrate, the match 107 includes a first branch circuit and a second branch circuit. Each branch circuit includes one or more match network elements. Examples of match network elements include capacitors, inductors, and resistors. An example of the plasma chamber 108 is a capacitively coupled plasma (CCP) chamber.

The host computer 106 includes a processor 114 and a memory device 116. Examples of the processor 114 include a central processing unit (CPU), an application specific integrated circuit (ASIC), and a programmable logic device (PLD). Examples of the memory device 116 include a read-only memory and a random-access memory.

The plasma chamber 108 includes a lower electrode LE and an upper electrode UE. A gap is formed between the lower electrode LE and the upper electrode UE and a substrate S is placed within the gap on a top surface of the lower electrode LE for processing. An example of the substrate S includes a semiconductor wafer on which an integrated circuit is fabricated.

The processor 114 is coupled to the memory device 116. The processor 114 is coupled via a transfer cable 118 to the LF RF generator 102 and via a transfer cable 120 to the HF RF generator 104. An example of a transfer cable includes an electric cable that transfers data in a parallel manner or in a serial manner or using a universal serial bus (USB) protocol. The LF RF generator 102 has an output 122 that is coupled via an RF cable 124 to an input 126 of the match 107. Similarly, the HF RF generator 104 has an output 128 that is coupled via an RF cable 130 to an input 132 of the match 107. The match 107 has an output 134, which is coupled via an RF transmission line 136 to the lower electrode LE. The first branch circuit of the match 107 is coupled between the input 126 and the output 134, and the second branch circuit of the match 107 is coupled between the input 132 and the output 134. The upper electrode UE is coupled to a ground potential.

The V sensor 110 is coupled via a transfer cable 138 to the processor 114 and the P sensor 112 is coupled via a transfer cable 140 to the processor 114. The V sensor 110 is coupled to the output 134 of the match 134. Also, the P sensor 112 is coupled to the output 128 of the HF RF generator 104. An output of the P sensor 112 is coupled to the HF RF generator 104. For example, the output of the P sensor 112 is coupled via a transfer cable 143 to a processor, such as a digital signal processor (DSP), of the HF RF generator 104.

The processor 114 generates a recipe signal 142, which includes a low frequency and one or more power levels of an RF signal 150 to be generated by the LF RF generator 102. As an example, the low frequency is equal to the frequency of operation of the LF RF generator 102. As an example, the one or more power levels includes one or more power amounts or one or more power values. To illustrate, a power level includes a single power amount. As another illustration, a power level includes multiple power amounts within a predetermined range. The processor 114 sends the recipe signal 142 via the transfer cable 118 to the LF RF generator 102. Also, the processor 114 generates a recipe signal 144, which includes a high frequency and one or more power levels of an RF signal 152 to be generated by the HF RF generator 104. As an example, the high frequency is equal to the frequency of operation of the HF RF generator 104. The processor 114 sends the recipe signal 144 via the transfer cable 120 to the HF RF generator 104.

Upon receiving the recipe signal 142, the LF RF generator 102 generates the RF signal 150 having the low frequency and the one or more power levels indicated within the recipe signal 142. The LF RF generator 102 sends the RF signal 150 via the output 122, the RF cable 124, and the input 126 to the match 107. Similarly, upon receiving the recipe signal 144, the HF RF generator 104 generates the RF signal 152 having the high frequency and the one or more power levels indicated within the recipe signal 144. The HF RF generator 104 sends the RF signal 152 via the output 128, the RF cable 130, and the input 132 to the match 107.

Upon receiving the RF signal 150, the first branch circuit of the match 107 matches an impedance of a load coupled to the output 134 with an impedance of a source coupled to the input 126 to modify an impedance of the RF signal 150 to provide a first modified RF signal. An example of the load coupled to the output 134 includes the RF transmission line 136 and the plasma chamber 108. An example of the source coupled to the input 126 includes the RF cable 124 and the LF RF generator 102. Similarly, upon receiving the RF signal 152, the second branch circuit of the match 107 matches an impedance of the load coupled to the output 134 of the match 107 with an impedance of a source coupled to the input 132 of the match 107 to modify an impedance of the RF signal 152 to provide a second modified RF signal.

The match 107 combines, such as adds, the first and second modified RF signals to output a modified RF signal 154 at the output 134. The modified RF signal 154 is sent from the output 134 via the RF transmission line 136 to the lower electrode LE. When one or more process gases, such as a fluorine-containing gas, an oxygen-containing gas, a nitrogen-containing gas, etc., are supplied to the gap between the lower electrode LE and the upper electrode UE, in addition to the modified RF signal 154, plasma is stricken or maintained within the gap. The plasma processes the substrate S. Examples of processing the substrate S include etching features within the substrate S, depositing materials on the substrate S, and cleaning the substrate S.

While the substrate S is being processed, the V sensor 110 measures a voltage at the output 134 to output a voltage signal 156 and sends the voltage signal 156 via the transfer cable 138 to the processor 114. Similarly, while the substrate S is being processed, the P sensor 112 measures power, such as delivered power or reflected power, at the output 134 to output a power signal 158 and sends the power signal 158 via the transfer cable 140 to the processor 114.

In an embodiment, the V sensor 110 is coupled at any point on the RF transmission line 136.

In one embodiment, the P sensor 112 is coupled at any point on the RF cable 130.

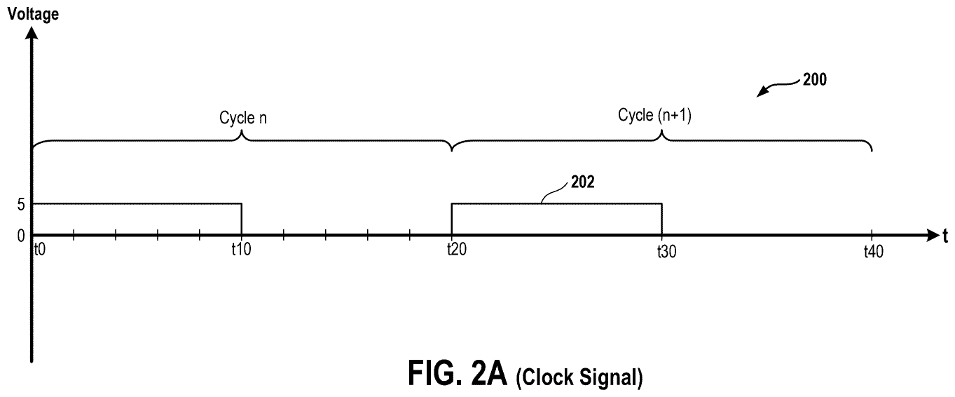

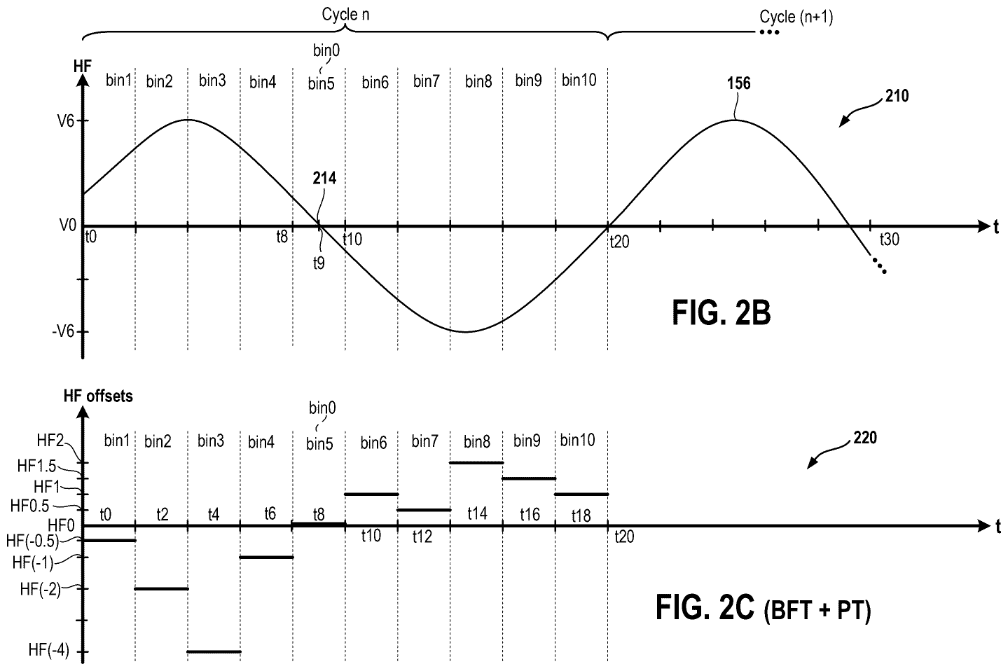

FIG. 2A is an embodiment of a graph 200 to illustrate a clock signal 202. As an example, the clock signal 202 is generated by the processor 114 (FIG. 1). An x-axis of the graph 200 plots time t ranging from a time to to a time t40. A y-axis of the graph 200 plots a voltage of the clock signal 202. The clock signal 202 transitions periodically between a logic level 1 and a logic level 0. The logic level 1 corresponds to 5 volts and the logic level 0 corresponds to zero volts.

The clock signal 202 transitions from the logic level 0 to the logic level 1 at the time t0 and remains at the logic level 1 from the time to to the time t10. At the time t10, the clock signal 202 transitions from the logic level 1 to the logic level 0, and remains at the logic level 0 from the time t10 to the time t20. The transitions between the logic levels 1 and 0 repeat from the time t20 to the time t40. The clock signal 202 has a cycle n from the time to to the time t20 and a consecutively following cycle (n+1) from the time t20 to the time t40, where n is a positive integer. The clock signal 202 has additional clock cycles, such as a clock cycle (n+2) and so on, after the clock cycle (n+1).

FIG. 2B is a graph 210 that plots an embodiment of the voltage signal 156, such as a delivered voltage signal, to illustrate binning. As an example, the graph 210 is generated by the processor 114 (FIG. 1) upon receiving the voltage signal 156 from the V sensor 110 (FIG. 1).

The graph 210 plots the voltage signal 156 versus the time t. For example, a y-axis of the graph 210 represents a voltage of the voltage signal 156 and an x-axis of the graph 210 represents the time t. The y-axis plots multiple voltage values, starting in a positive y-direction, from V0 to V6. Also, the y-axis plots multiple voltage values, starting in a negative y-direction, from V0 to −V6. The voltage value V6 is greater than the voltage value V0 and the voltage value −V6 is less than the voltage value V0. To illustrate, the voltage value V0 is zero. As another illustration, the voltage value V0 is negative. As an example, the x-axis of the graph 210 represents the time t at which the voltage values of the voltage signal 156 are received by the processor 114 from the V sensor 110.

The voltage signal 156 represents a voltage of the first modified RF signal or primarily represents a voltage of the RF signal 150 generated by the LF RF generator 102. For example, the voltage signal 156 represents the voltage of the RF signal 150. As another example, the voltage signal 156 primarily represents the voltage of the RF signal 150 and minimally represents a voltage of the RF signal 152 generated by the HF RF generator 104 (FIG. 1). To illustrate, a voltage of the voltage signal 156 is a voltage of the RF signal 150. As another illustration, 90% of a voltage of the voltage signal 156 is a voltage of the RF signal 150 and the remaining 10% of the voltage of the voltage signal 156 is a voltage of the RF signal 152. The voltage signal 156 extends over multiple clock cycles of the clock signal 202 (FIG. 2A). For example, the voltage signal 156 extends from the time to to the time t20, and the time interval between the times t0 to t20 represents the cycle n of the clock signal 202. The voltage signal 156 further extends from the time t20 to the time t40, and the time interval between the times t20 to t40 represents the cycle (n+1) of the clock signal 202.

The processor 114 divides the voltage signal 156 during each cycle of the clock signal 202 into multiple bins, such as 10 or 20 bins. For example, during the cycle n, the voltage signal 156 is divided into bins 1 through 10 of a cycle of the voltage signal 156, and during the cycle (n+1), the voltage signal 156 is divided into bins 1 through 10 of another cycle of the voltage signal 156, and so on. To illustrate, the processor 114 divides the voltage signal 156 during each cycle of the clock signal 202. In the illustration, the voltage signal 156 is divided into ten equal time intervals during each cycle, and each time interval is designated by the processor 114 as a bin.

The processor 114 extends each bin across the same time interval. For example, the bin 1 extends from the time to to the time t2, the bin 2 extends from the time t2 to the time t4, the bin 3 extends from the time t4 to the time t6, the bin 4 extends from the time t6 to the time t8, and the bin 5 extends from the time t8 to the time t10. The bin 5 is sometimes referred to herein as a bin 0. Also, the bin 6 extends from the time t10 to the time t12, the bin 7 extends from the time t12 to the time t14, the bin 8 extends from the time t14 to the time t16, the bin 9 extends from the time t16 to the time t18, and the bin 10 extends from the time t18 to the time t20.

The processor 114 identifies the bin 0 as a time interval that includes a point at which the voltage signal 156 intersects the x-axis and determines the point to be a negative zero crossing 214. For example, the processor 114 determines the point at which a voltage of the voltage signal 156 is zero and a slope of the voltage signal 156 is negative to be the negative zero crossing 214. The slope of the voltage signal 156 is negative during the time interval of the bin 0. As another example, at the negative zero crossing 214, a voltage of the voltage signal 156 is non-zero.

The processor 114 identifies, such as designates, one of the bins 1 through 10 that include the negative zero crossing 214 to be the bin 0. For example, the bin 5 is designated as the bin 0. The bins 1 through 4 and a first portion of the bin 0 form a positive cycle of the voltage signal 156 and a second portion of the bin 0 and the bins 6 through 10 form a negative cycle of the voltage signal 156. A sum of the positive and negative cycles of the voltage signal 156 forms a cycle of the voltage signal 156. The first portion of the bin 0 that is a part of the positive cycle of the voltage signal 156 extends for a time interval from the time t8 to the time t9 at which the negative crossing 214 occurs. Also, the second portion of the bin 0 that is a part of the negative cycle of the voltage signal 156 extends for a time interval from the time t9 to the time t10.

FIG. 2C is a diagram of an embodiment of a graph 220 to illustrate generation of HF offset values, which are frequency values, at which the HF RF generator 104 (FIG. 1) is to be operated during processing of the substrate S. When the HF RF generator 104 operates at the frequency of operation, the HF RF generator 104 generates the RF signal 152 (FIG. 1) having multiple frequency offsetting values, which are also frequency values. The graph 220 is generated by the processor 114 (FIG. 1). The graph 220 plots the HF offset values, which are offsets from a reference high frequency value HF0 of the RF signal 152, on a y-axis versus the time t. The reference high frequency value HF0 is a frequency of the RF signal 152 during the bin 0. The time t is plotted on an x-axis of the graph 220. For example, the x-axis of the graph 210 (FIG. 2B) is used as the x-axis of the graph 220.

The y-axis of the graph 220 plots the HF offset values from the high frequency value HF0. The HF offset values range from HF0 to HF2 in the positive y-direction and from HF0 to HF(-4) in the negative y-direction. It should be noted that the HF offset values increase from HF0 to HF2 and decrease from HF0 to HF(-4). For example, the HF offset value HF1 is greater than the high frequency value HF0 and the HF offset value HF2 is greater than the HF offset HF1 and so on. Similarly, the HF offset value HF(-1) is less than the high frequency value HF0 and the HF offset value HF(-2) is less than the HF offset value HF(-1) and so on.

It should be noted that an HF offset value or a frequency offsetting value is an offset, such as an addition or a subtraction, from the reference high frequency value HF0 of the RF signal 152. For example, the HF offset HF(-0.5) is lower than the reference high frequency value HF0 by −0.5 MHz and the HF offset HF2 is greater than the reference high frequency value HF0 by 2 MHz. As another example, a first frequency offsetting value is lower than the reference high frequency value HF0 by −0.4 MHz and a second frequency offsetting value is greater than the reference high frequency value HF0 by 1.4 MHz. In this manner, the HF RF generator 104, which has the frequency of operation of 60 MHz, operates within a range of frequency values, such as between 57 MHz to 63 MHz during each cycle of the clock signal 202.

As illustrated in the graph 220, the processor 114 applies the HF offsets and the reference high frequency value HF0 during each cycle of the clock signal 202. For example, the processor 114 controls the HF RF generator 104 to operate at the HF offset value HF(-0.5) during the bin 1, the HF offset value HF(-2) during the bin 2, the HF offset value HF(-4) during the bin 3, the HF offset value HF(-1) during the bin 4, the reference high frequency value HF0 during the bin 0, the HF offset value HF1 during the bin 6, the HF offset value HF0.5 during the bin 7, the HF offset value HF2 during the bin 8, the HF offset value HF1.5 during the bin 9, and the HF offset value HF1 during the bin 10. To illustrate, the processor 114 sends the recipe signal 144 (FIG. 1) indicating that the HF RF generator 104 generate the RF signal 152 having the HF offset (−0.5) during the bin 1 and indicating that the HF RF generator 104 generate the RF signal 152 having the HF offset (−2) during the bin 2, and so on. In the illustration, upon receiving the recipe signal 144, the HF RF generator 104 generates the RF signal 152 having the HF offset (−0.5) during the bin 1 and having the HF offset (−2) during the bin 2, and so on. The application of the reference high frequency value HF0 is sometimes referred to herein as a bin frequency tuning method (BFT), and the determination of the HF offsets based on the reference high frequency value HF0 and a power parameter or application of the HF offsets or both the determination and application is sometimes referred to herein as a pyramid tuning (PT) method.

During a frequency tuning operation, each HF offset value for a bin is determined and applied by the processor 114 based on a corresponding, such as a respective, frequency offsetting value and the power parameter, such as a voltage reflection coefficient (gamma or Γ) or a voltage standing wave ratio (VSWR), for the bin. For example, during a bin M of a cycle Y, such as the cycle n or a cycle (n−p), of the clock signal 202 of processing the substrate S, the processor 114 controls the HF RF generator 104 to operate at a respective frequency offsetting value, such as the first frequency offsetting value, and receives multiple power values of the power signal 158 (FIG. 1) from the P sensor 112, where M is any integer 1 through 4 and 5 through 10, p is an integer less than the integer n, and Z is an integer. In the example, the respective frequency offsetting value is stored in the memory device 116 for access by the processor 114. Further, in the example, the processor 114 determines the power parameter from the power values for the bin M of the cycle Y when the HF RF generator 104 operates at the respective frequency offsetting value. Also, in the example, the processor 114 accesses, from the memory device 116 (FIG. 1), a value of forward power, which is power that is supplied by the HF RF generator 104, during the bin M of the cycle Y. In the example, the processor 114 calculates a first statistical delivered power value, such as an average or a median, from the power values received from the P sensor 112 during the bin M of the cycle Y when the HF RF generator 104 operates at the respective frequency offsetting value. In the example, the first statistical delivered power value is of power delivered by the HF RF generator 104 during the bin M of the cycle Y. Also, in the example, the processor 114 subtracts the first statistical delivered power value from the forward power value for the bin M of the cycle Y to determine a first value of reflected power for the bin M of the cycle Y. In the example, the processor 114 calculates a ratio of the first value of reflected power for the bin M of the cycle Y to the forward power value during the bin M of the cycle Y to calculate a first power reflection coefficient for the bin M. Also, in the example, the processor 114 computes a square root of the first power reflection coefficient for the bin M of the cycle Y to calculate a first voltage reflection coefficient for the bin M of the cycle Y.

Continuing with the example, during the bin M of a cycle Z, such as the cycle (n−p) or a cycle (n−p+q) or the cycle n, of the clock signal 202 of processing the substrate S, the processor 114 controls the HF RF generator 104 to modify the respective frequency offsetting value to a respective HF offset value, such as the HF offset value HF(-0.5), and receives multiple power values of the power signal 158 (FIG. 1) from the P sensor 112, where q is an integer and the integer (n−p+q) is greater than the integer (n−p) but less than the integer n. In the example, the respective HF offset value is stored in the memory device 116 for access by the processor 114. Further, in the example, the processor 114 determines the power parameter from the power values for the bin M of the cycle Z when the HF RF generator 104 operates at the respective HF offset value. In the example, the processor 114 accesses, from the memory device 116 (FIG. 1), the value of forward power, which is power that is supplied by the HF RF generator 104, during the bin M of the cycle Z. In the example, the processor 114 calculates a second statistical delivered power value, such as an average or a median, from the power values received from the P sensor 112 during the bin M of the cycle Z when the HF RF generator 104 operates at the respective HF offset value. In the example, the second statistical delivered power value is of power delivered by the HF RF generator 104 during the bin M. Also, in the example, the processor 114 subtracts the second statistical delivered power value during the bin M of the cycle Z from the forward power value for the bin M of the cycle Z to determine a second value of reflected power for the bin M of the cycle Z. Further, in the example, the processor 114 calculates a ratio of the second value of reflected power for the bin M of the cycle Z to the forward power value during the bin M of the cycle Z to calculate a second power reflection coefficient for the bin M of the cycle Z. Also, in the example, the processor 114 computes a square root of the second power reflection coefficient for the bin M of the cycle Z to calculate a second voltage reflection coefficient for the bin M of the cycle Z.

Continuing with the example, the processor 114 compares the second voltage reflection coefficient with the first voltage reflection coefficient to determine that the second voltage reflection coefficient is less than the first voltage reflection coefficient. The processor 114, in the example, determines to operate the HF RF generator 104 at the respective HF offset value during the bin M of the cycles n, (n+1) and so on upon determining that the second voltage reflection coefficient is less than the first voltage reflection coefficient. On the other hand, in the example, the processor 114 determines to operate the HF RF generator 104 at the respective frequency offsetting value during the bin M of the cycles n, (n+1) and so on upon determining that the first voltage reflection coefficient is less than the second voltage reflection coefficient.

As another example, instead of comparing the second voltage reflection coefficient with the first voltage reflection coefficient, the processor 114 compares the first voltage reflection coefficient or the second voltage reflection coefficient with a predetermined value to determine whether to operate the HF RF generator 104 at the respective frequency offsetting value or the respective HF offset value during the bin M of the cycles n, (n+1) and so on. To illustrate, upon determining that the first voltage reflection coefficient is greater than the predetermined value and the second voltage reflection coefficient is less than the predetermined value, the processor 114 determines to operate the HF RF generator 104 at the respective HF offset value during the bin M of the cycles n, (n+1), and so on. In the illustration, on the other hand, upon determining that the second voltage reflection coefficient is greater than the predetermined value and the first voltage reflection coefficient is less than the predetermined value, the processor 114 determines to operate the HF RF generator 104 at the respective frequency offsetting value during the bin M of the cycles n, (n+1), and so on.

Also, as another example, the processor 114 determines a ratio of a first sum and a first difference to output a first VSWR. Continuing with the example, the first sum is a total of 1 and the first voltage reflection coefficient. In the example, the first difference is a difference between 1 and the first voltage reflection coefficient. Further, in the example, the processor 114 determines a ratio of a second sum and a second difference to output a second VSWR. Continuing with the example, the second sum is a total of 1 and the second voltage reflection coefficient. Also, in the example, the second difference is a difference between 1 and the second voltage reflection coefficient. In the example, the processor 114 compares the second VSWR with the first VSWR to determine that the second VSWR is less than the first VSWR. The processor 114, in the example, determines to operate the HF RF generator 104 at the respective HF offset value during the bin M of the cycles n, (n+1) and so on upon determining that the second VSWR is less than the first VSWR. By operating the HF RF generator 104 at the respective HF offset value during the bin M of the cycles n, (n+1) and so on, the processor 114 applies the respective HF offset value to the HF RF generator 104. Further, in the example, the processor 114 determines to operate the HF RF generator 104 at the respective frequency offsetting value during the bin M of the cycles n, (n+1) and so on upon determining that the first VSWR is less than the second VSWR. By operating the HF RF generator 104 at the respective frequency offsetting value during the bin M of the cycles n, (n+1) and so on, the processor 114 applies the respective frequency offsetting value to the HF RF generator 104.

As another example, instead of comparing the second VSWR with the first VSWR, the processor 114 compares the first VSWR or the second VSWR with a predetermined value to determine whether to operate the HF RF generator 104 at the respective frequency offsetting value or the respective HF offset value during the bin M of the cycles n, (n+1) and so on. To illustrate, upon determining that the first VSWR is greater than the predetermined value and the second VSWR is less than the predetermined value, the processor 114 determines to operate the HF RF generator 104 at the respective HF offset value during the bin M of the cycles n, (n+1), and so on. In the illustration, on the other hand, upon determining that the second VSWR is greater than the predetermined value and the first VSWR is less than the predetermined value, the processor 114 determines to operate the HF RF generator 104 at the respective frequency offsetting value during the bin M of the cycles n, (n+1), and so on.

It should be noted that as an example, the reflected power is power reflected towards the HF RF generator 104 from the plasma chamber 108, the RF transmission line 136, the match 107, and the RF cable 130 (FIG. 1). The power reflected towards the HF RF generator 104 is sometimes referred to herein as high frequency reflected power.

In an embodiment, a frequency offsetting value is sometimes referred to herein as an HF offset.

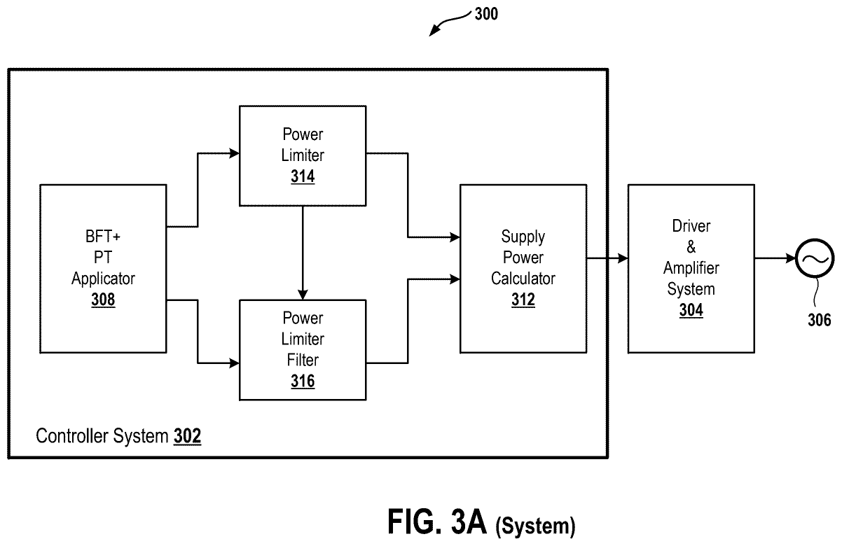

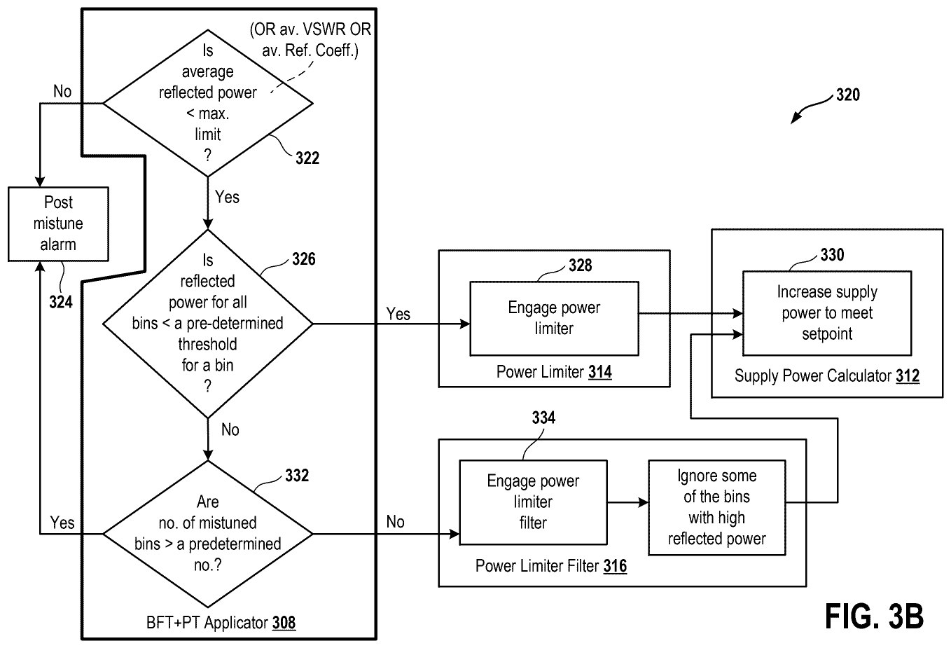

FIG. 3A is a diagram of an embodiment of a system 300 to illustrate a power limiter filter 316. The system 300 includes a controller system 302, a driver and amplifier system 304, and a power supply 306. The driver and amplifier system 304 includes a driver and an amplifier. For example, the driver is coupled to the power limiter filter 316 at one end and to the amplifier at an opposite end. An example of the driver includes one or more transistors. An example of the power supply 306 is an electronic oscillator that generates an RF signal having a sinusoidal waveform.

The controller system 302 includes a BFT +PT applicator 308, which is referred to herein as the applicator 308. An example of the applicator 308 is a processor, such as the processor 114 (FIG. 1), or a controller. An example of a controller, as described herein, is a DSP, a microcontroller, a combination of one or more processors and one or more memory devices, an ASIC and a PLD. The controller system 302 further includes a supply power calculator 312, a power limiter 314, and a power limiter filter 316. As an example, the applicator 308 is a part or a component of the host computer 106 (FIG. 1). In the example, the power limiter 314, the power limiter filter 316, and the supply power calculator 312 are parts or components of a controller of the HF RFG 104. Also, in the example, the driver and amplifier system 304 and the power supply 306 are components of the HF RFG 104. To illustrate, functionality, described herein, of the applicator 308 is implemented by the processor 114 and functionality, described herein, of the power limiter 314, the power limiter filter 316, and the supply power calculator 312 is implemented by the DSP of the HF RF generator 104. To further illustrate, the processor 114 executes functions, described herein, as being performed by the applicator 308. An example of the supply power calculator 312 is a processor, such as the DSP of the HF RF generator 104, or a controller of the HF RF generator 104. Also, an example of the power limiter 314 is a processor or a controller, an example of the power limiter filter 316 is a processor or a controller, and an example of the supply power calculator 312 is a processor or a controller.

The applicator 308 is coupled to the power limiter 314 and the power limiter filter 316. The power limiter filter 316 is coupled to the power limiter 314. For example, the applicator 308 is coupled to the power limiter 314 and to the power limiter filter 316 via the transfer cable 120 (FIG. 1). The power limiter 314 and the power limiter filter 316 are coupled to the supply power calculator 312. The supply power calculator 312 is coupled to the driver 304, which is coupled to the power supply 306. Functionality of the controller system 302 is described below with reference to FIG. 3B.

In one embodiment, functionality, described herein, of one or more of the applicator 308, the supply power calculator 312, the power limiter 314, and the power limiter filter 316 is implemented or executed by one or more controllers. For example, the functions of the one or more of the applicator 308, the supply power calculator 312, the power limiter 314, and the power limiter filter 316 are implemented or executed by the processor 114. As another example, the functions of the one or more of the applicator 308, the supply power calculator 312, the power limiter 314, and the power limiter filter 316 are implemented or executed by a controller of the HF RF generator

FIG. 3B is a flowchart to illustrate an embodiment of a method 320 for determining whether to limit power that is supplied by the HF RFG 104 (FIG. 1). The method 320 is executed by the controller system 302 (FIG. 3A).

The method 320 includes an operation 322, which is executed by the applicator 308 (FIG. 3A). The operation 322 is performed during the cycle Y. When the HF RF generator 104 is operated at the respective frequency offsetting values for the bins 1 through 10 during the cycle Y, the processor 114 receives the high frequency reflected power from the P sensor 112 during a time interval for each the bins 1 through 10, and calculates an average reflected power from the high frequency reflected power. For example, the processor 114 receives a value RPI of the high frequency reflected power during the bin 1, a value RP2 of the high frequency reflected power during the bin 2, and so on until it receives a value RP10 of the high frequency reflected power during the bin 10. In the example, the processor 114 calculates an average of the high frequency reflected power received during the bins 1 through 10 to determine the average reflected power. To illustrate, the processor 114 calculates an average of the RPI through RP10 values by dividing a sum of the values RPI through RP10 by 10. In the operation 322, the processor 114 compares the average reflected power with a maximum limit to determine whether the average reflected power is less than the maximum limit. The maximum limit is a value stored in the memory device 116 (FIG. 1). The maximum limit is received from a user via an input device for storing in the memory device 116. Examples of the input device include a keyboard, a mouse, a keypad, and the status. The input device is coupled to the processor 114 via an input/output interface. As another example, instead of the average reflected power, an average VSWR or an average voltage reflection coefficient is used. It should be noted that the average VSWR or the average voltage reflected coefficient are representative of the average reflected power.

Upon determining that the average reflected power is not less than, such as equal to or greater than, the maximum limit, the processor 114 posts a mistune alarm in an operation 324 of the method 320. For example, the processor 114 controls a display device to generate a notification indicating that the high frequency of the HF RF generator 104 is being mistuned. The processor 114 is coupled to the display device. Examples of the display device include a liquid crystal display (LCD), a light emitting diode (LED) display, and a plasma display.

On the other hand, upon determining that the average reflected power is less than the maximum limit, in an operation 326 of the method 320, the applicator 308 determines whether the high frequency reflected power for a number of bins, such as all of the bins 1 through 10, during the cycle of the voltage signal 156 is less than a predetermined threshold for one of the number of bins. The operation 326 is performed during the cycle Y. The predetermined threshold for the one of the bins is stored in the memory device 116 and is received from the user via the input device.

To determine whether the high frequency reflected power is less than the predetermined threshold, the applicator 308 compares the high frequency reflected power for each of the bins within the cycle of the voltage signal 156 to the predetermined threshold. For example, the applicator 308 compares the value of the high frequency reflected power RP1 with the predetermined threshold to determine whether the value is less than the predetermined threshold. In the example, the applicator 308 compares each of the values RP2 through RP10 with the predetermined threshold to determine whether each of the values RP2 through RP10 is less than the predetermined threshold. Further in the example, upon determining that each of the values RP1 through RP10 is lower than the predetermined threshold, the applicator 308 determines that the high frequency reflected power for the number of bins is less than the predetermined threshold. In the example, the other hand, upon determining that at least one of the values RP1 through RP10 is not lower than, such as equal to or greater than, the predetermined threshold, the applicator 308 determines that the high frequency reflected power for the number of bins is not less than the predetermined threshold

Upon determining that the high frequency reflected power for the number of bins is less than the predetermined threshold, the applicator 308 engages the power limiter 314 in an operation 328 of the method 320. Also, upon engaging the power limiter 314, the applicator 308 controls, in an operation 330 of the method 320, the HF RF generator 104 (FIG. 1) to increase the forward power of the RF signal 152 (FIG. 1) to meet a setpoint. For example, in the operation 320, the processor 104 sends a signal to the power limiter 314 via the transfer cable 120 (FIG. 1) to limit, such as cap, the increase in the amount of the forward power of the RF signal 152. Also in the example, the applicator 308 sends an instruction to the supply power calculator 312 via the transfer cable 120 to increase the forward power that is supplied by the HF RF generator 104 until the setpoint is achieved or until the limit is achieved, whichever comes first. Further, in the example, a copy of the instruction sent to the supply power calculator 312 is sent to the power limiter 314.

To illustrate, upon receiving the signal to limit the increase in the amount of forward power of the RF signal 152 during the cycle Z, the power limiter 314 is engaged, such as triggered, and upon being triggered, the power limiter 314 determines to limit, such as cap, the increase in the amount of forward power of the RF signal 152. In the example, the increase in the amount of power is to be limited during the cycle Z. In the illustration, the power limiter 314 determines that the increase in the amount of forward power within the instruction to the supply power calculator 312 can result in damage to components of the driver and amplifier system 304 (FIG. 3A), and so determines to limit the increase in the amount of forward power to a prelimited amount. In the illustration, the power limiter 314 accesses the prelimited amount from a memory device of the HF RF generator 104 and reduces the increase in the amount of forward power to the prelimited amount of power.

In the illustration, upon determining to limit the supply of power by the HF RF generator 104 to the prelimited amount of power, the power limiter 314 generates and sends, during the cycle Z, a control signal to the supply power calculator 312. Further, in the illustration, upon receiving the control signal, the supply power calculator 312 sends a command signal to the driver and amplifier system 304 to limit, such as reduce, the increase in the amount of forward power of the RF signal 152 to the prelimited amount. Also, in the illustration, upon receiving the command signal to achieve the limit, the driver of the driver and amplifier system 304 generates a current signal based on the prelimited amount and sends the current signal to the amplifier of the driver and amplifier system 304. In the illustration, upon receiving the current signal, the amplifier amplifies, such as increases or decreases an amplitude, of the current signal to achieve the limit in the amount of power of the RF signal 152 to the prelimited amount to output an amplified signal, and sends the amplified signal to the RF power supply 306. Further in the illustration, upon receiving the amplified signal, the RF power supply 306 generates the amount of power of the RF signal 152 to achieve the prelimited amount during the cycle Z.

On the other hand, upon determining that the high frequency reflected power for the number of bins is not less than the predetermined threshold, in an operation 332 of the method 320, the applicator 308 determines if a number of mistuned bins is greater than a predetermined number. The operation 332 is performed during the cycle Y. For example, based on the comparison in the operation 326, the applicator 308 determines that for each of the bins 1, 2, and 4, the high frequency reflected power is not less than the predetermined threshold, and therefore, determines that the bins 1, 2, and 4 are mistuned. To illustrate, the processor 114 controls the HF RF generator 104 to operate at the respective frequency offsetting values for each of the bins 1, 2, and 4, and compares the high frequency reflected power received from the P sensor 112 during each of the bins 1, 2, and 4 with the predetermined threshold to determine that the high frequency reflected power is not less than the predetermined threshold for each of the bins 1, 2, and 4.

Further, in the example, the applicator 308 counts a number of the bins 1, 2, and 4 to generate the number, such as three, of mistuned bins. Also, in the example, the applicator 308 compares the number three with the predetermined number to determine whether the number three is greater than the predetermined number. In the example, upon determining that the number three is greater than the predetermined number, the applicator 308 determines that the number of bins is greater the predetermined number. Further, in the example, on the other hand, upon determining that the number three is equal to or less than the predetermined number, the applicator 308 determines that the number of mistuned bins is less than the predetermined number.

Upon determining that the number of mistuned bins is greater than the predetermined number, the operation 324 is performed. On the other hand, upon determining that the number of mistuned bins is not greater than, such as equal to or less than, the predetermined number, the applicator 308 sends a signal to the power limiter filter 316 to engage the power limiter filter 316.

The power limiter filter 316 is engaged in an operation 334 of the method 320. By engaging the power limiter filter 316, the number of mistuned bins of the operation 332 are ignored by the power limiter filter 316 and the power limiter 314. Also, upon engaging the power limiter filter 316, the applicator 308 controls, in the operation 330 of the method 320, the HF RF generator 104 (FIG. 1) to increase the forward power of the RF signal 152 (FIG. 1) to meet the setpoint. For example, in the operation 334, the processor 104 sends the signal to the power limiter 314 to engage the power limiter 314 and simultaneously sends a signal to the power limiter filter 316 via the transfer cable 120 (FIG. 1) to engage the power limiter filter 316. In the example, the signal is sent to the power limiter filter 316 to control, such as reduce or remove or not apply, the limit in the increase in the amount of the forward power of the RF signal 152. Also in the example, the applicator 308 sends an instruction to the supply power calculator 312 via the transfer cable 120 to increase the forward power that is supplied by the HF RF generator 104 until the setpoint is achieved. In the example, a copy of the instruction to increase the forward power is sent to the power limiter 314 and the power limiter filter 316.

To illustrate, upon receiving the signal to increase the amount of forward power of the RF signal 152 during the cycle Z, the power limiter 314 and the power limiter filter 316 are engaged, such as triggered. In the illustration, upon being triggered, the power limiter 314 determines to limit, such as cap, the increase in the amount of forward power of the RF signal 152 to the prelimited amount. In the illustration, the increase in the amount of power is to be limited during the cycle Z. Also, in the illustration, when the power limiter filter 316 is triggered, the power limiter filter 316 determines to control the limit in the increase in the amount of forward power of the RF signal 152. In the illustration, the power limiter 314 accesses the prelimited amount from a memory device of the HF RF generator 104 and reduces the increase in the amount of forward power to the prelimited amount of power and provides the prelimited amount to the power limiter filter 316.

In the illustration, upon determining to control the limit in the supply of power by the HF RF generator 104, the power limiter filter 316 generates and sends, during the cycle Z, a control signal to the supply power calculator 312 to remove or reduce the prelimited amount. Further, in the illustration, upon receiving the control signal, the supply power calculator 312 sends a command signal to the driver and amplifier system 304 to control, such as reduce or remove, the limit in the increase in the amount of forward power of the RF signal 152. Also, in the illustration, upon receiving the command signal to control the limit, the driver of the driver and amplifier system 304 generates a current signal based on the control signal and sends the current signal to the amplifier of the driver and amplifier system 304. In the illustration, upon receiving the current signal, the amplifier amplifies, such as increases or decreases an amplitude, of the current signal to achieve the setpoint of the forward power of the RF signal 152 to output an amplified signal, and sends the amplified signal to the RF power supply 306. Further in the illustration, upon receiving the amplified signal, the RF power supply 306 generates the amount of power of the RF signal 152 to achieve the setpoint during the cycle Z.

As such, in the method 320, in the operation 322, a tune quality is represented by an average value, such as the average voltage reflection coefficient or the average VSWR or the average reflected power, and the power limiter 314 and the power limiter filter 316 are operated based on the average power. Sometimes, the set point is a lower power set point. When the set point is the low power set point, the tune quality is ignored and the lower power set point is delivered by increasing the forward power. It is safe to increase the forward power because the HF RF generator 104 is not as risk if the high frequency reflected power for the number of bins is below the predetermined threshold.

It should be noted that in an embodiment, some of the operations described above can be executed in more than one cycle of the clock signal 202.

Embodiments, described herein, may be practiced with various computer system configurations including hand-held hardware units, microprocessor systems, microprocessor-based or programmable consumer electronics, minicomputers, mainframe computers and the like. The embodiments, described herein, can also be practiced in distributed computing environments where tasks are performed by remote processing hardware units that are linked through a computer network.

In some embodiments, a controller is part of a system, which may be part of the above-described examples. The system includes semiconductor processing equipment, including a processing tool or tools, chamber or chambers, a platform or platforms for processing, and/or specific processing components (a wafer pedestal, a gas flow system, etc.). The system is integrated with electronics for controlling its operation before, during, and after processing of a semiconductor wafer or substrate. The electronics is referred to as the “controller,” which may control various components or subparts of the system. The controller, depending on processing requirements and/or a type of the system, is programmed to control any process disclosed herein, including a delivery of process gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks connected to or interfaced with the system.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, DSPs, chips defined as ASICs, PLDs, one or more microprocessors, or microcontrollers that execute program instructions (e.g., software). The program instructions are instructions communicated to the controller in the form of various individual settings (or program files), defining operational parameters for carrying out a process on or for a semiconductor wafer. The operational parameters are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

The controller, in some embodiments, is a part of or coupled to a computer that is integrated with, coupled to the system, otherwise networked to the system, or a combination thereof. For example, the controller is in a “cloud” or all or a part of a fab host computer system, which allows for remote access for wafer processing. The controller enables remote access to the system to monitor current progress of fabrication operations, examines a history of past fabrication operations, examines trends or performance metrics from a plurality of fabrication operations, to change parameters of current processing, to set processing steps to follow a current processing, or to start a new process.

In some embodiments, a remote computer (e.g., a server) provides process recipes to the system over a computer network, which includes a local network or the Internet. The remote computer includes a user interface that enables entry or programming of parameters and/or settings, which are then communicated to the system from the remote computer. In some examples, the controller receives instructions in the form of settings for processing a wafer. It should be understood that the settings are specific to a type of process to be performed on a wafer and a type of tool that the controller interfaces with or controls. Thus, as described above, the controller is distributed, such as by including one or more discrete controllers that are networked together and working towards a common purpose, such as the fulfilling processes described herein. An example of a distributed controller for such purposes includes one or more integrated circuits on a chamber in communication with one or more integrated circuits located remotely (such as at a platform level or as part of a remote computer) that combine to control a process in a chamber.

Without limitation, in various embodiments, a plasma system, described herein, includes a plasma etch chamber, a deposition chamber, a spin-rinse chamber, a metal plating chamber, a clean chamber, a bevel edge etch chamber, a physical vapor deposition (PVD) chamber, a chemical vapor deposition (CVD) chamber, an atomic layer deposition (ALD) chamber, an atomic layer etch (ALE) chamber, an ion implantation chamber, a track chamber, or any other semiconductor processing chamber that is associated or used in fabrication and/or manufacturing of semiconductor wafers.

It is further noted that although the above-described operations are described with reference to a parallel plate plasma chamber, e.g., a capacitively coupled plasma chamber, etc., in some embodiments, the above-described operations apply to other types of plasma chambers, e.g., a plasma chamber including an inductively coupled plasma (ICP) reactor, a transformer coupled plasma (TCP) reactor, conductor tools, dielectric tools, a plasma chamber including an electron cyclotron resonance (ECR) reactor, etc. For example, an X MHz RF generator, a Y MHz RF generator, and a Z MHz RF generator are coupled to an inductor within the ICP plasma chamber.

As noted above, depending on a process operation to be performed by the tool, the controller communicates with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

With the above embodiments in mind, it should be understood that some of the embodiments employ various computer-implemented operations involving data stored in computer systems. These computer-implemented operations are those that manipulate physical quantities.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

In some embodiments, the operations, described herein, are performed by a computer selectively activated, or are configured by one or more computer programs stored in a computer memory, or are obtained over a computer network. When data is obtained over the computer network, the data may be processed by other computers on the computer network, e.g., a cloud of computing resources.

One or more embodiments, described herein, can also be fabricated as computer-readable code on a non-transitory computer-readable medium. The non-transitory computer-readable medium is any data storage hardware unit, e.g., a memory device, etc., that stores data, which is thereafter read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although some method operations, described above, were presented in a specific order, it should be understood that in various embodiments, other housekeeping operations are performed in between the method operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment described above are combined with one or more features of any other embodiment without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein, but may be modified within the scope and equivalents of the appended claims.

1. A method for controlling a limit on power supplied by a high frequency (HF) radio frequency (RF) generator, comprising:
determining whether average power reflected towards the HF RF generator is less than a maximum limit;
determining whether power reflected towards the HF RF generator for a number of bins during a cycle is less than a predetermined threshold upon determining that the average power is less than the maximum limit;
determining whether a number of mistuned bins is greater than a predetermined number in response to determining that the power reflected towards the HF RF generator for the number of bins during the cycle is not less than the predetermined threshold; and
engaging a power limiter filter upon determining that the number of mistuned bins is not greater than the predetermined number.

2. The method of claim 1, further comprising engaging a power limiter upon determining that the power reflected towards the HF RF generator for the number of bins during the cycle is less than the predetermined threshold.

3. The method of claim 2, further comprising increasing the power supplied by the HF RF generator upon engaging the power limiter.

4. The method of claim 1, further comprising increasing the power supplied by the HF RF generator upon engaging the power limiter filter.

5. The method of claim 1, further comprising posting a mistune alarm upon determining that the average power reflected towards the HF RF generator is not less than the maximum limit.

6. The method of claim 1, further comprising posting a mistune alarm upon determining that the number of mistuned bins is greater than the predetermined number.

7. The method of claim 1, wherein the number of bins include all of the bins during the cycle.

8. The method of claim 1, wherein the cycle is of a voltage signal at an output of an impedance matching circuit that is coupled to the HF RF generator.

9. A controller for controlling a limit on power supplied by a high frequency (HF) radio frequency (RF) generator, comprising:
a processor configured to:
determine whether average power reflected towards the HF RF generator is less than a maximum limit;
determine whether power reflected towards the HF RF generator for a number of bins during a cycle is less than a predetermined threshold upon determining that the average power is less than the maximum limit;
determine whether a number of mistuned bins is greater than a predetermined number in response to determining that the power reflected towards the HF RF generator for the number of bins during the cycle is not less than the predetermined threshold; and
engage a power limiter filter upon determining that the number of mistuned bins is not greater than the predetermined number; and
a memory device coupled to the processor.

10. The controller of claim 9, wherein the processor is configured to engage a power limiter upon determining that the power reflected towards the HF RF generator for the number of bins during the cycle is less than the predetermined threshold.

11. The controller of claim 10, wherein the processor is configured to increase the power supplied by the HF RF generator upon engaging the power limiter.

12. The controller of claim 9, wherein the processor is configured to increase the power supplied by the HF RF generator upon engaging the power limiter filter.

13. The controller of claim 9, wherein the processor is configured to post a mistune alarm upon determining that the average power reflected towards the HF RF generator is not less than the maximum limit.

14. The controller of claim 9, wherein the processor is configured to post a mistune alarm upon determining that the number of mistuned bins is greater than the predetermined number.

15. The controller of claim 9, wherein the number of bins include all of the bins during the cycle.

16. The controller of claim 9, wherein the cycle is of a voltage signal at an output of an impedance matching circuit that is coupled to the HF RF generator.

17. A plasma system for controlling a limit on power supplied by a high frequency (HF) radio frequency (RF) generator, comprising:
a low frequency (LF) RF generator configured to generate an LF RF signal;
an HF RF power supply configured to generate an HF RF signal;
a match coupled to the LF and HF RF generators to receive the LF and HF RF signals to output a modified signal;
a plasma chamber coupled to the match to receive the modified signal; and
a controller coupled to the HF RF power supply, wherein the controller is configured to:
determine whether average power reflected towards the HF RF generator is less than a maximum limit;
determine whether power reflected towards the HF RF generator for a number of bins during a cycle is less than a predetermined threshold upon determining that the average power is less than the maximum limit;
determine whether a number of mistuned bins is greater than a predetermined number in response to determining that the power reflected towards the HF RF generator for the number of bins during the cycle is not less than the predetermined threshold; and
engage a power limiter filter upon determining that the number of mistuned bins is not greater than the predetermined number.

18. The plasma system of claim 17, wherein the controller is configured to engage a power limiter upon determining that the power reflected towards the HF RF generator for the number of bins during the cycle is less than the predetermined threshold.

19. The plasma system of claim 18, wherein the controller is configured to increase the power supplied by the HF RF generator upon engaging the power limiter.

20. The plasma system of claim 17, wherein the controller is configured to increase the power supplied by the HF RF generator upon engaging the power limiter filter.
